(19) United States
(12) Patent Application Publication
(10) Pub. No.: US 2026/0255509 A1
(43) Pub. Date: Aug. 27, 2026

(54) MULTI-FUNCTIONAL INTEGRATED TESTING ATTACHMENT FOR ROTATIONAL RHEOMETER

(71) Applicant: Lanzhou University, Lanzhou (CN)

(72) Inventors: Fanyu ZHANG, Lanzhou (CN); Ruihua HAO, Lanzhou (CN)

(21) Appl. No.: 19/648,967

(22) Filed: Apr. 15, 2026

(30) Foreign Application Priority Data
Jan. 23, 2026 (CN) 202610095489.8

(51) Int. Cl. H05K 5/02; G01L 19/00; G01N 11/14

(52) U.S. Cl. CPC H05K 5/0217; G01L 19/0092; G01N 11/14

(57) ABSTRACT

The present disclosure discloses a multi-functional integrated testing attachment for a rotational rheometer, comprising a testing attachment and a fixing plate. The testing attachment is divided into a stage assembly and a testing assembly, the testing assembly comprises a micro-pore water pressure gauge, a microseismometer, and an acoustic emission instrument. The stage assembly comprises the upper section of the stage assembly and the lower section of the stage assembly, the upper section of the stage assembly is arranged above the lower section of the stage assembly. The microseismometer is arranged externally on the upper section of the stage assembly and is elevated above the upper section of the stage assembly. The present disclosure adopts the multi-functional integrated testing attachment for a rotational rheometer, the main body of the stage is fixedly connected to the microseismometer through the fixing plate.

### TECHNICAL FIELD

The present disclosure relates to the technical field of rotational rheometers, specifically to a multi-functional integrated testing attachment for a rotational rheometer.

### BACKGROUND

Rheology is the science that studies the flow and deformation of matter, primarily focusing on the phenomena of liquid flow and solid deformation. Its research subjects encompass a wide range of fluids, such as air, water, blood, crude oil, toothpaste, cement mortar, sludge, polymer solutions, and paint. Applications span numerous fields, including the petroleum industry, medical devices, chemical engineering, and food processing. Furthermore, rheology is increasingly gaining importance in the field of earth sciences. Research subjects include dam-break floods, debris flows, landslides, pyroclastic flows, submarine gravity flows, as well as soft matter flows on planetary surfaces such as Mars and the Moon. These involve the rapid spreading of natural mixtures of granular materials and water (natural dense suspensions) over complex terrains and various sedimentary substrates. The unpredictable nature resulting from complex flow behaviors is the root cause of their significant hazards.

Rheological properties are crucial for fluids, such as the operational efficiency of automotive engine lubricants, the transportation of crude oil through pipelines, grouting in construction, and the adhesion capability of paint. For different types of fluids, various methods are available to test their rheological behaviors. These include capillary viscometry for purely viscous fluids, extensional rheometers for high-viscosity polymers, efficient and reliable rotational rheometers, slump test commonly used for cement mortar, as well as simple-to-operate methods like the falling ball and rolling ball techniques. Rotational rheometers achieve broad material applicability by replacing measurement systems and selecting attachments such as concentric cylinder systems, vane systems, parallel plate systems, cone-plate systems, and double-gap systems. This enables testing of low/high-viscosity fluids, melts, gels, suspensions, and soft solids.

With the continuous advancement of modern testing methods and characterization techniques, the collaborative testing capabilities of rheometers have been significantly expanded. The development and application of various attachments have enabled more accurate and diverse characterization of the microstructural evolution of materials under complex stress conditions. The introduction of attachments such as optical microscopy, confocal microscopy, small-angle laser scattering (SALS), dielectric spectroscopy, and Raman spectroscopy has enabled structural observation from the micron to nanometer scales. These techniques can correlate physicochemical behaviors such as crystallization, cross-linking, and electrical properties under shear fields, deepening the understanding of material structure-performance relationships.

However, existing technical approaches still primarily focus on the characterization of microscopic morphology and chemical structure, with insufficient detection of the physical behaviors and dynamic processes of fluids within porous media such as geomaterials. Currently, there is a lack of integrated attachments capable of simultaneously monitoring key physical parameters such as pore water pressure, micro-fracture events, and particle vibration behaviors. This leads to limitations in understanding the rheological mechanisms of complex systems like geophysical flows. Additionally, attaching external sensors during rheological testing often leads to issues such as asynchronous measurements across multiple devices and difficulties in aligning data temporally and spatially. Simultaneously, external probes can disrupt the flow field and compromise specimen integrity, thereby affecting the reliability of experimental results.

To address this, we have developed a multi-functional integrated test attachment to expand the characterization dimensions of rotational rheometers. This solution aims to achieve synchronous, in-situ measurement of macroscopic rheological parameters and microscopic physical behaviors. Through a built-in, integrated design, it avoids reliance on external sensors, thereby maintaining sample integrity and flow field stability while enabling high spatiotemporal resolution capture of multi-physical field parameters such as pore pressure and micro-fracture signals. This provides key technical support for in-depth exploration of the rheological mechanisms of complex systems like geophysical flows.

### SUMMARY

An objective of the present disclosure is to provide a multi-functional integrated testing attachment for a rotational rheometer, which integrates sensors such as a micro-pore water pressure gauge, microseismometer, and acoustic emission instrument into a testing attachment to realize synchronous measurement of various test methods. This attachment is applicable to various stages of different rotational rheometers, including parallel plate stages, concentric cylinder stages, and double-gap stages, among others.

The present disclosure provides a multi-functional integrated testing attachment for a rotational rheometer, including a testing attachment and a fixing plate. The testing attachment is divided into a stage assembly and a testing assembly. The testing assembly includes a micro-pore water pressure gauge, a microseismometer, and an acoustic emission instrument. The stage assembly includes an upper section of the stage assembly and a lower section of the stage assembly, the upper section of the stage assembly is arranged above the lower section of the stage assembly. The microseismometer is arranged externally on the upper section of the stage assembly and is elevated above the upper section of the stage assembly.

In some embodiments, the lower section of the stage assembly is provided with a through-hole, and the lower section of the stage assembly is fixedly connected to the upper section of the stage assembly through two connecting bolts.

In some embodiments, the upper section of the stage assembly is fixedly connected to the microseismometer through the fixing plate.

In some embodiments, the upper section of the stage assembly includes the micro-pore water pressure gauge, the acoustic emission instrument, and a rough surface, an upper surface of the upper section of the stage assembly is a rough surface.

In some embodiments, a roughness of the rough surface may be adjusted according to number of surface protrusions, ranging from very rough to smooth.

In some embodiments, one side of the fixing plate is arc-shaped, the other side of the fixing plate is a plane, the arc-shaped side of the fixing plate is connected to the upper section of the stage assembly, and the side of the plane in the fixing plate is connected to the microseismometer.

In some embodiments, a through-hole with internal threads is arranged at a center of the upper section of the stage assembly, an end of the micro-pore water pressure gauge is provided with external threads, and the micro-pore water pressure gauge is arranged flush with the rough surface.

In some embodiments, the acoustic emission instrument is arranged inside the upper section of the stage assembly, and a spring is arranged below the acoustic emission instrument.

Therefore, the present disclosure adopts the multi-functional integrated testing attachment for a rotational rheometer, and integrates the micro-pore water pressure gauge, acoustic emission instrument, and microseismometer into the stage assembly to form a testing attachment to realize a synchronous measurement of rheological parameters, pore water pressure, micro-fracture events, and particle vibration behavior.

The technical scheme of the present disclosure is further described in detail through the embodiments.

### BRIEF DESCRIPTION OF THE DRAWINGS

FIG. 1 is an overall schematic diagram of the multi-functional integrated testing attachment for a rotational rheometer according to the present disclosure;

FIG. 2 is a schematic diagram of the internal structure of the upper section of the stage assembly of the multi-functional integrated testing attachment for a rotational rheometer according to the present disclosure;

FIG. 3 is a schematic diagram of the internal structure of the lower section of the stage assembly of the multi-functional integrated testing attachment for a rotational rheometer according to the present disclosure.

Marks in the FIG.

1, stage assembly; 2, fixing plate; 3, microseismometer; 4, connecting bolt; 11, upper section of the stage assembly; 12, lower section of the stage assembly; 101, micro-pore water pressure gauge; 102, acoustic emission instrument; 103, rough surface of the stage assembly.

### DETAILED DESCRIPTION

The following is a further explanation of the technical scheme of the present disclosure through drawings and embodiments.

Unless otherwise defined, the technical terms or scientific terms used in the present disclosure should be understood by people with general skills in the field to which the present disclosure belongs.

The words “first”, “second”, and the like used in this present disclosure do not represent any order, quantity, or importance, but are only used to distinguish different components. Similar words, such as “include” or “contain,” mean that the elements or objects appearing before the word cover the elements or objects listed after the word and their equivalents, without excluding other elements or objects. Similar words such as “connected” or “coupled” are not limited to physical or mechanical connections, but can include electrical connections, whether direct or indirect. “Up”, “down”, “left”, and “right” are only used to represent the relative positional relationship. When the absolute position of the described object changes, the relative positional relationship may also change accordingly.

### Embodiment 1

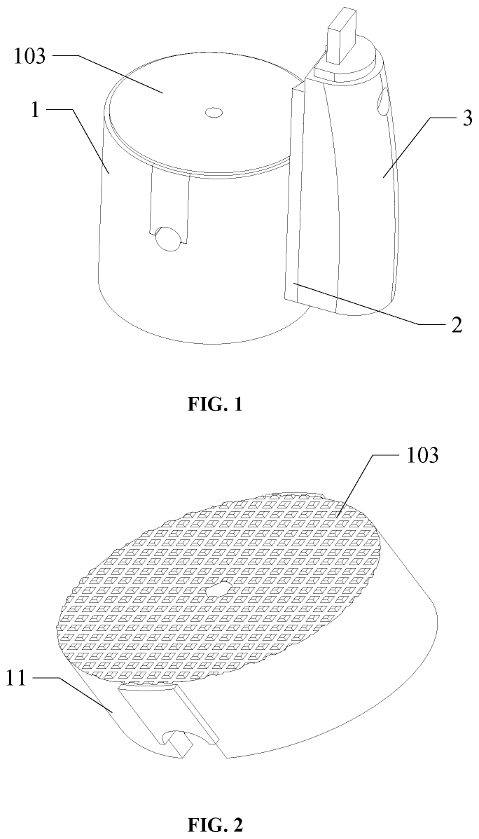

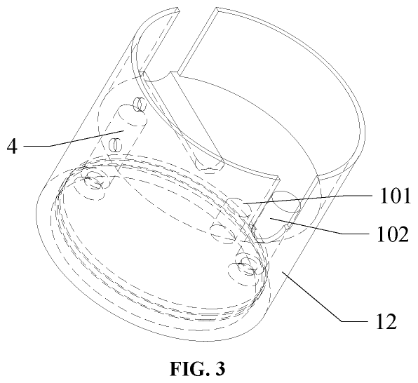

As shown in FIGS. 1-3, the multi-functional integrated testing attachment for a rotational rheometer includes a testing attachment, a fixing plate 2, and a microseismometer 3. The testing attachment is divided into a stage assembly 1 and a testing assembly, the testing assembly includes a micro-pore water pressure gauge 101, a microseismometer, and an acoustic emission instrument 102. The stage assembly 1 includes the upper section of the stage assembly 11 and the lower section of the stage assembly 12. The upper section of the stage assembly 11 is arranged above the lower section of the stage assembly 12. The thickness of the stage assembly 1 is 6 cm, which not only ensures the stability of the testing attachment, but also takes into account the portability. The materials of the fixing plate 2, the upper section of the stage assembly 11, and the lower section of the stage assembly 12 are all stainless steel.

During the sample testing process, the sample is positioned exactly in the middle above the upper section of the stage assembly 11 in the stage assembly 1. The commonly used sample size is 2 mm×φ20 mm, and the height of the sample is adjustable. The lower section of the stage assembly 12 provides stable support for the upper section of the stage assembly 11 to ensure the stability of the whole device. The lower section of the stage assembly 12 is connected to the temperature control component, enabling rapid heating and cooling.

There is a through-hole arranged on the lower section of the stage assembly 12, to make a stable connection with the upper section of the stage assembly 11, the lower section of the stage assembly 12 is fixedly connected to the upper section of the stage assembly 11 through the two connecting bolts 4. The lower section of the stage assembly 12 and the upper section of the stage assembly 11, may achieve a close and detachable connection. The connecting bolt 4 is used as a fastener, and its head and screw assembly pass through the corresponding through-holes of the lower section of the stage assembly 12 and the upper section of the stage assembly 11, respectively, along with the fastening connection is realized by tightening the nut.

The microseismometer 3 is arranged externally on the upper section of the stage assembly 11 and the microseismometer 3 is elevated above the upper section of the stage assembly 11, which is more effective in receiving and recording vibration signals. The upper section of the stage assembly 11 is fixedly connected to the microseismometer 3 through the fixing plate 2, which not only ensures the stability of the microseismometer 3, but also facilitates its maintenance and replacement. The microseismometer 3 receives the vibration signals. The fixing plate 2 not only plays a connecting role, but also ensures that the microseismometer 3 will not move or shake due to external interference when receiving the vibration signals, thereby improving the accuracy of monitoring.

The interior of the upper section of the stage assembly 11 provided with a micro-pore water pressure gauge 101, an acoustic emission instrument 102, and a rough surface 103. The upper surface of the upper section of the stage assembly 11 is a rough surface 103. The roughness of the rough surface 103 may be adjusted according to the number of surface protrusions, ranging from very rough to smooth.

One side of the fixing plate 2 is arc-shaped, and the other side of the fixing plate 2 is flat, enabling the fixing plate 2 to fit and securely connect components of different shapes, the arc-shaped side of the fixing plate 2 is connected to the upper section of the stage assembly 11, which helps to better fit the shape of the upper section of the stage assembly 11 and ensure the tightness and stability of the connection. The flat side of the fixing plate 2 is connected to the microseismometer 3, and the flat design facilitates contact with the smooth surface of the microseismometer 3.

The micro-pore water pressure gauge 101 is required to contact with the tested sample during the measurement process, the through-hole with internal threads is arranged at the center of the upper section of the stage assembly 11, the size of the through-hole is φ5 mm, and the size of the through-hole is adapted to the size of the micro-pore water pressure gauge 101. The micro-pore water pressure gauge 101 is provided with external threads at the end. The micro-pore water pressure gauge 101 is fixed after being screwed into the through-hole to ensure its stability. The micro-pore water pressure gauge 101 is arranged flush with the rough surface 103, it ensures that the measuring end surface of the micro-pore water pressure gauge 101 may be in close contact with the tested sample, so as to meet the measurement requirements. After installing the micro-pore water pressure gauge 101, it is consistent with the test plane and meets the contact requirements with the sample.

There is a cylindrical cavity arranged on one side of the through-hole, which reserves spaces for the acoustic emission instrument 102. The size of the cylindrical cavity is 2 cm×φ3 cm, which ensures that the acoustic emission instrument 102 may be stably placed in the cylindrical cavity. There is an acoustic emission instrument 102 arranged in the cylindrical cavity. The acoustic emission instrument 102 is arranged inside the upper section of the stage assembly 11, which not only protects the acoustic emission instrument 102, but also facilitates the accurate measurement of the acoustic emission instrument 102. The acoustic emission instrument 102 accepts the transient elastic wave generated by the rapid release of energy during the friction process. The signal is transmitted through the elastic wave without direct contact with the sample, the non-contact measurement method not only simplifies the experimental steps, but also improves the accuracy and reliability of the measurement. There is a spring arranged under the acoustic emission instrument 102 to ensure a close fit and avoid wave refraction caused by the gap.

Therefore, the present disclosure adopts the multi-functional integrated testing attachment for a rotational rheometer, integrates the micro-pore water pressure gauge, acoustic emission instrument, and microseismometer into the stage assembly to form a testing attachment to realize the synchronous measurement of rheological parameters, pore water pressure, micro-fracture events, and particle vibration behavior. It is compatible with a variety of rotational rheometer stages, and may be extended to concentric cylinders, vanes, cones, double gaps, and other measurement systems by adjusting the arrangement and connection of components.

The above embodiments are only used to explain the technical scheme of the present disclosure rather than to restrict it. Although the present disclosure is described in detail with reference to the embodiments, ordinary technicians in this field should understand that they may still modify or replace the technical scheme of the present disclosure, and these modifications or equivalent replacements cannot make the modified technical scheme out of the spirit and scope of the technical scheme of the present disclosure.

What is claimed is:

1. A multi-functional integrated testing attachment for a rotational rheometer, comprising a testing attachment and a fixing plate, the testing attachment is divided into a stage assembly and a testing assembly. The testing assembly comprises a micro-pore water pressure gauge, a microseismometer, and an acoustic emission instrument. The stage assembly comprises an upper section of the stage assembly and a lower section of the stage assembly, the upper section of the stage assembly is arranged above the lower section of the stage assembly. The microseismometer is arranged externally on the upper section of the stage assembly and is elevated above the upper section of the stage assembly.

2. The multi-functional integrated testing attachment for a rotational rheometer according to claim 1, wherein the lower section of the stage assembly is provided with a through-hole, and the lower section of the stage assembly is fixedly connected to the upper section of the stage assembly through two connecting bolts.

3. The multi-functional integrated testing attachment for a rotational rheometer according to claim 1, wherein the upper section of the stage assembly is fixedly connected to the microseismometer through the fixing plate.

4. The multi-functional integrated testing attachment for a rotational rheometerhe according to claim 1, wherein the upper section of the stage assembly comprises the micro-pore water pressure gauge, the acoustic emission instrument and a rough surface, an upper surface of the upper section of the stage assembly is a rough surface, a roughness of the rough surface may be adjusted according to number of surface protrusions, ranging from very rough to smooth.

5. The multi-functional integrated testing attachment for a rotational rheometerhe according to claim 1, wherein one side of the fixing plate is arc-shaped, other side of the fixing plate is flat, the arc-shaped side of the fixing plate is connected to the upper section of the stage assembly, and the flat side of the fixing plate is connected to the microseismometer.

6. The multi-functional integrated testing attachment for a rotational rheometer according to claim 1, wherein a through-hole with internal threads is arranged at a center of the upper section of the stage assembly, an end of the micro-pore water pressure gauge is provided with external threads, and the micro-pore water pressure gauge is arranged flush with the rough surface.

7. The multi-functional integrated testing attachment for a rotational rheometer according to claim 1, wherein the acoustic emission instrument is arranged inside the upper section of the stage assembly, and a spring is arranged below the acoustic emission instrument.
